(19) United States
(12) Patent Application Publication
(10) Pub. No.: US 2023/0354626 A1
(43) Pub. Date: Nov. 2, 2023

(54) IMAGING DEVICE

(71) Applicant: Panasonic Intellectual Property Management Co., Ltd., Osaka (JP)

(72) Inventors: TAKANORI DOI, Kyoto (JP); TAKAMICHI YOKOYAMA, Kanagawa (JP); TAKAHIRO KOYANAGI, Osaka (JP)

(21) Appl. No.: 18/333,609

(22) Filed: Jun. 13, 2023

Related U.S. Application Data
(63) Continuation of application No. PCT/JP2021/045237, filed on Dec. 9, 2021.

(30) Foreign Application Priority Data
Jan. 6, 2021 (JP) 2021-000903

(51) Int. Cl. H10K 39/32

(52) U.S. Cl. CPC H10K 39/32

(57) ABSTRACT

An imaging device includes a pixel electrode, a counter electrode facing the pixel electrode, and a photoelectric conversion layer located between the pixel electrode and the counter electrode. The counter electrode includes a first transparent electrode, a second transparent electrode, and an intermediate layer located between the first transparent electrode and the second transparent electrode. A material of the intermediate layer is different from a material of the first transparent electrode and different from a material of the second transparent electrode. The photoelectric conversion layer, the first transparent electrode, the intermediate layer, and the second transparent electrode are arranged in this order. The intermediate layer contains an insulating material as a major ingredient.

### BACKGROUND

### 1. Technical Field

The present disclosure relates to an imaging device.

### 2. Description of the Related Art

For an imaging device such as a CMOS (complementary metal-oxide semiconductor) image sensor, a structure has been proposed in which a photoelectric conversion film formed of an organic material is utilized as a photoelectric converter. For example, Japanese Patent No. 4815233 or Japanese Patent No. 6128020 discloses a configuration of an imaging device including a plurality of pixel electrodes arrayed in rows and columns on top of a substrate, an organic layer including a photoelectric conversion layer provided on top of the plurality of pixel electrodes and commonly to the plurality of pixel electrodes, and a translucent counter electrode provided on top of the organic layer and commonly to the plurality of pixel electrodes. The imaging device uses the photoelectric conversion layer to absorb light having entered through the translucent counter electrode and convert the light into electrons and holes. At this point in time, applying a voltage between the pixel electrodes and the counter electrode makes it possible to efficiently take out carriers generated in the photoelectric conversion layer. In such translucent counter electrodes, indium tin oxide (ITO) is widely used, as it is desirably high in transmittance and low in resistance.

### SUMMARY

In one general aspect, the techniques disclosed here feature an imaging device including at least one pixel electrode, a counter electrode facing the at least one pixel electrode, and a photoelectric conversion layer located between the at least one pixel electrode and the counter electrode. The counter electrode includes a first transparent electrode, a second transparent electrode, and an intermediate layer located between the first transparent electrode and the second transparent electrode. A material of the intermediate layer is different from a material of the first transparent electrode. The material of the intermediate layer is different from a material of the second transparent electrode. The photoelectric conversion layer, the first transparent electrode, the intermediate layer, and the second transparent electrode are arranged in this order. The intermediate layer contains an insulating material as a major ingredient.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 is a cross-sectional view showing an example of a photoelectric conversion element of an imaging device according to an embodiment;

FIG. 2 is a plan view showing the example of the photoelectric conversion element of the imaging device according to the embodiment;

FIG. 3 is a cross-sectional view showing an example of a photoelectric conversion element of an imaging device according to Modification 1 of the embodiment;

FIG. 4 is a plan view showing the example of the photoelectric conversion element of the imaging device according to Modification 1 of the embodiment;

FIG. 5 is a cross-sectional view showing an example of a photoelectric conversion element of an imaging device according to Modification 2 of the embodiment;

FIG. 6 is a plan view showing the example of the photoelectric conversion element of the imaging device according to Modification 2 of the embodiment;

FIG. 7 is a cross-sectional view showing an example of a photoelectric conversion element of an imaging device according to Modification 3 of the embodiment;

FIG. 8 is a plan view showing the example of the photoelectric conversion element of the imaging device according to Modification 3 of the embodiment;

FIG. 9 is a circuit diagram showing a circuit configuration of the imaging device according to the embodiment;

FIG. 10 is a cross-sectional view of a unit pixel of the imaging device according to the embodiment; and

FIG. 11 is a diagram showing results of measurement of the frequency-capacitance characteristics of the photoelectric conversion elements under dark conditions in Example and Comparative Examples 1 to 3.

### DETAILED DESCRIPTIONS

In the conventional imaging device described above, the optical and electrical characteristics of the translucent counter electrode may greatly vary according to the film quality of the translucent counter electrode. For this reason, in a case where the film quality of the counter electrode varies, the imaging device may suffer performance variations.

One non-limiting and exemplary embodiment provides an imaging device with reduced performance variations.

### Brief Overview of the Present Disclosure

In one general aspect, the techniques disclosed here feature an imaging device including an imaging device including at least one pixel electrode, a counter electrode facing the at least one pixel electrode, and a photoelectric conversion layer located between the at least one pixel electrode and the counter electrode. The counter electrode includes a first transparent electrode, a second transparent electrode, and an intermediate layer located between the first transparent electrode and the second transparent electrode. The intermediate layer is made of a material that is different from both that of which the first transparent electrode is made and that of which the second transparent electrode is made. The photoelectric conversion layer, the first transparent electrode, the intermediate layer, and the second transparent electrode are arranged in this order. The intermediate layer contains an insulating material as a major ingredient. Therefore, the second transparent electrode is located opposite the photoelectric conversion layer behind the first transparent electrode.

In a case where the first transparent electrode and the second transparent electrode are in contact with each other, the film quality of the first transparent electrode may change due to the influence of the second transparent electrode. On the other hand, the imaging device according to the present aspect, in which the intermediate layer can inhibit a change in film quality of the first transparent electrode, can reduce variations in the optical and electrical characteristics of the first transparent electrode. This makes it possible to provide an imaging device with reduced performance variations.

Further, the intermediate layer, which contains the insulating material, makes it possible to separate the first transparent electrode and the second transparent electrode from each other. This inhibits a change in film quality of the first transparent electrode due to the influence of the second transparent electrode, thus making it possible to reduce variations in the optical and electrical characteristics of the first transparent electrode.

Further, for example, the intermediate layer may have a film thickness greater than or equal to 3 nm.

Further, for example, the insulating material may be aluminum oxide.

This makes it possible to inhibit crystallization of the first transparent electrode even in a case where heat is applied in the process of manufacture, as aluminum oxide has a pinning effect. This reduces variations in the optical and electrical characteristics of the first transparent electrode, thus making it possible to provide an imaging device with reduced performance variations.

Further, for example, the intermediate layer may have a film thickness less than or equal to 5 nm.

This produces the tunnel effect of allowing passage of electrons through the intermediate layer, as the film thickness of the intermediate layer is sufficiently small. This makes it possible to, without interfering with electrical continuity between the first transparent electrode and the second transparent electrode, achieve a counter electrode that is highly capable of injecting electrons into the photoelectric conversion layer and that is low in resistance. This makes it possible to enhance the performance of the imaging device.

Further, for example, the first transparent electrode may be larger in crystallite size than the second transparent electrode.

The first transparent electrode, which is larger in crystallite size, is highly capable of injecting electrons into the photoelectric conversion layer. Meanwhile, the second transparent electrode, which is smaller in crystallite size, is low in electrical resistance. Joining such a first transparent electrode and such a second transparent electrode on top of each other makes it possible to achieve a counter electrode that is highly capable of injecting electrons into the photoelectric conversion layer and that is low in resistance.

Further, for example, the first transparent electrode and the second transparent electrode may each contain indium tin oxide as a major ingredient.

This makes it possible to, by utilizing ITO, achieve a counter electrode that is highly transparent to visible light, that is highly capable of injecting electrons into the photoelectric conversion layer, and that is low in resistance.

Further, for example, the at least one pixel electrode may include a plurality of pixel electrodes, the plurality of pixel electrodes may be arranged in a matrix in a plan view, and the intermediate layer may be provided across the plurality of pixel electrodes in the plan view.

This causes the intermediate layer to be provided, for example, with a uniform film thickness all over a so-called pixel region. This allows the intermediate layer to exert a protective effect uniformly within the region, thus a change in film quality of the first transparent electrode can be suppressed.

Further, for example, the imaging device according to the aspect of the present disclosure may further include an extraction electrode placed in a position that is different from a position of each of the plurality of pixel electrodes in the plan view and that is electrically connected to the counter electrode. The first transparent electrode and the second transparent electrode may overlap the extraction electrode in the plan view. The first transparent electrode may be in contact with the extraction electrode.

This makes it possible to satisfactorily feed electricity to the counter electrode.

Further, for example, the intermediate layer may overlap the extraction electrode in the plan view.

This allows the first transparent electrode, the second transparent electrode, and the intermediate layer to be patterned collectively. This makes it possible to reduce the number of patterning mask alignment steps, thus making it possible to enhance producibility of imaging devices.

Further, for example, the intermediate layer may not overlap the extraction electrode in the plan view.

This makes it possible to make an electrical connection between the extraction electrode and the counter electrode with low resistance.

Further, for example, the intermediate layer may cover a side surface of the photoelectric conversion layer.

This makes it possible to inhibit characteristic degradation near the side surface of the photoelectric conversion layer.

In the following, embodiments are specifically described with reference to the drawings.

It should be noted that the embodiments to be described below each illustrate a comprehensive and specific example. The numerical values, shapes, materials, constituent elements, placement and topology of constituent elements, steps, orders of steps, or other features that are shown in the following embodiments are just a few examples and are not intended to limit the present disclosure. Further, those of the constituent elements in the following embodiments which are not recited in an independent claim are described as optional constituent elements.

Further, the drawings are schematic views and are not necessarily strict illustrations. Accordingly, for example, the drawings are not necessarily to scale. Further, in the drawings, substantially the same components are given the same reference signs, and a repeated description may be omitted or simplified.

Further, terms such as “vertical” and “horizontal” used herein to show the way in which elements are interrelated, terms such as “rectangle” used herein to show the shape of an element, and ranges of numerical values used herein are not expressions that represent only exact meanings but expressions that are meant to also encompass substantially equivalent ranges, e.g. differences of approximately several percent.

Further, the terms “above” and “below” used herein do not refer to an upward direction (upward in a vertical direction) and a downward direction (downward in a vertical direction) in absolute space recognition, but are used as terms that are defined by a relative positional relationship on the basis of an order of lamination in a laminated configuration. Further, the terms “above” and “below” are applied not only in a case where two constituent elements are placed at a spacing from each other and another constituent element is present between the two constituent elements, but also in a case where two constituent elements are placed in close contact with each other and the two constituent elements touch each other.

Further, the clause “A contains B as a major ingredient”, which herein means that the content of B in A is higher than 50% by mass of the total mass of A, may also mean higher than or equal to 60% by mass, higher than or equal to 70% by mass, higher than or equal to 80% by mass, higher than or equal to 90% by mass, higher than or equal to 95% by mass, and higher than or equal to 99% by mass.

Further, unless otherwise noted, ordinal numbers such as “first” and “second” herein do not mean the number or order of constituent elements but are used for the purpose of avoiding confusion of constituent elements of the same kind and distinguishing between them.

### Embodiment

### 1. Configuration of Photoelectric Conversion Element

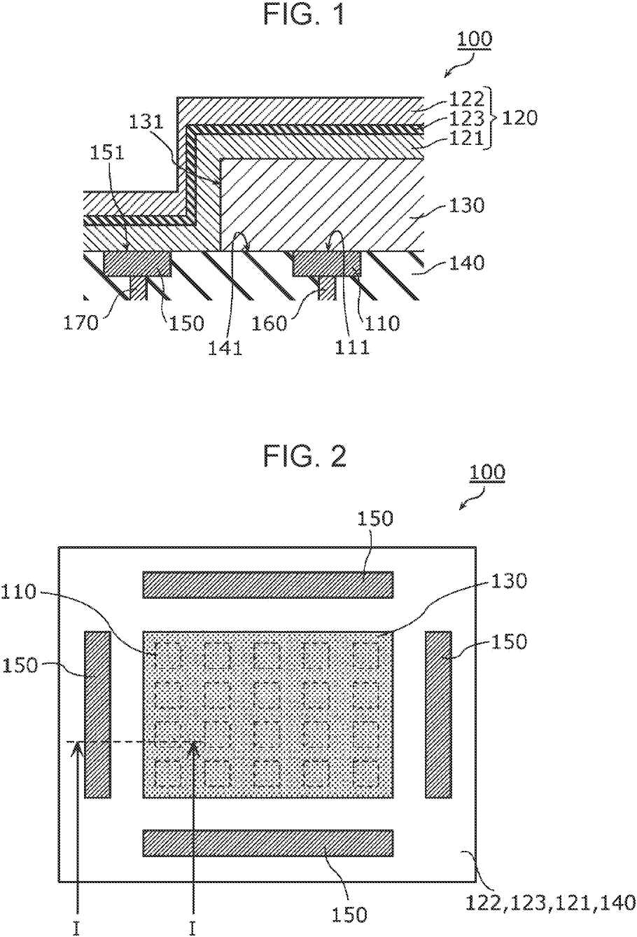

First, a brief overview of a photoelectric conversion element of an imaging device according to an embodiment is given with reference to FIGS. 1 and 2.

FIG. 1 is a cross-sectional view of a photoelectric conversion element 100 according to the present embodiment. FIG. 2 is a plan view of the photoelectric conversion element 100 according to the present embodiment. Specifically, FIG. 1 represents a cross-section taken along line I-I of FIG. 2. It should be noted that a specific configuration of an imaging device including the photoelectric conversion element 100 shown in FIGS. 1 and 2 will be described later.

As shown in FIG. 1, the photoelectric conversion element 100 includes a pixel electrode 110, a counter electrode 120, a photoelectric conversion layer 130, and an extraction electrode 150. The photoelectric conversion element 100 is provided on top of an insulating layer 140.

The insulating layer 140 is an insulating layer formed above a substrate (not illustrated). It should be noted that the substrate is provided, for example, with a transistor or other devices included in a signal processing circuit that processes signal charge generated by the photoelectric conversion element 100. Examples of the insulating layer 140 include, but are not limited to, single-layer or laminated structures of tetraethyl orthosilicate (TEOS), a silicon oxide film, a silicon nitride film, or other films.

The pixel electrode 110 is an electrode layer for trapping signal charge generated in the photoelectric conversion layer 130. As a material of which the pixel electrode 110 is made, an electrically-conductive material such as a metal, a metal oxide, a metal nitride, or electrically-conductive polysilicon is used. The metal is for example aluminum, silver, copper, titanium, tungsten, or other metals. The metal nitride is for example titanium nitride, tantalum nitride, or other metal nitrides. The electrically-conductive polysilicon is polysilicon given electrical conductivity by the addition of an impurity.

A plurality of the pixel electrodes 110 are provided in a region in which the photoelectric conversion layer 130 is provided in planar view. As shown in FIG. 2, the plurality of pixel electrodes 110 are arranged in rows and columns in planar view. It should be noted that the number of pixel electrodes 110 shown in FIG. 2 is merely an example and is not limited to particular numbers. The same applies to FIGS. 4, 6, and 8, which will be described later.

To each of the plurality of pixel electrodes 110, a connecting wire 160 shown in FIG. 1 is connected. The connecting wire 160 is part of a wire that electrically connects the pixel electrode 110 to a signal processing circuit. The connecting wire 160 is a via conductor the extends in a direction parallel with the thickness of the insulating layer 140. As a material of which the connecting wire 160 is made, an electrically-conductive material such as a metal, a metal oxide, a metal nitride, or electrically-conductive polysilicon is used.

The extraction electrode 150 is a feeding terminal for feeding electricity to the counter electrode 120. The extraction electrode 150 is electrically connected to the counter electrode 120. As a material of which the extraction electrode 150 is made, an electrically-conductive material such as a metal, a metal oxide, a metal nitride, or electrically-conductive polysilicon is used.

The extraction electrode 150 is placed in a position that is different from that of the plurality of pixel electrodes 110 in planar view. Specifically, the extraction electrode 150 is placed around the region in which the photoelectric conversion layer 130 is provided. That is, the extraction electrode 150 does not overlap the photoelectric conversion layer 130 in planar view. As shown in FIG. 2, four extraction electrodes 150 are provided in positions at a predetermined distance from each side of the rectangular photoelectric conversion layer 130 and in an elongated shape extending along a corresponding side. It should be noted that the number of extraction electrodes 150 may be only 1 or may be 2. To each of the one or more extraction electrodes 150, a connecting wire 170 shown FIG. 1 is connected.

The connecting wire 170 is part of a wire that electrically connects the extraction electrode 150 to a power supply circuit (not illustrated) that supplies a voltage that is applied to the counter electrode 120. The connecting wire 170 is a via conductor the extends in a direction parallel with the thickness of the insulating layer 140. As a material of which the connecting wire 170 is made, an electrically-conductive material such as a metal, a metal oxide, a metal nitride, or electrically-conductive polysilicon is used.

In the present embodiment, a principal surface of the extraction electrode 150 and a principal surface of the pixel electrode 110 are located at the same level in a direction of lamination. Specifically, an upper surface 151 of the extraction electrode 150 and an upper surface 111 of the pixel electrode 110 are located at the same level in the direction of lamination. In the present embodiment, the upper surface 151 of the extraction electrode 150, the upper surface 111 of the pixel electrode 110, and an upper surface 141 of the insulating layer 140 are flush with one another.

The counter electrode 120 is an electrode layer placed opposite the pixel electrode 110. The counter electrode 120 traps charge that is opposite in polarity to signal charge that the pixel electrode 110 traps. To the counter electrode 120, a predetermined voltage is applied. This makes a potential difference between the counter electrode 120 and the plurality of pixel electrodes 110, so that an electric field is applied to the photoelectric conversion layer 130. The counter electrode 120 traps charge that, among holes and electrons generated in the photoelectric conversion layer 130, migrates toward the counter electrode 120 under the influence of the electric field.

The counter electrode 120 has translucency to light that the photoelectric conversion layer 130 photoelectrically converts. Specifically, the counter electrode 120 is transparent to visible light. The term “transparent” means a sufficiently high transmittance to light. The transmittance of the counter electrode 120 to a predetermined wavelength in a band of visible light is higher than 50%, but may be higher than 60%, higher than 70%, higher than 80%, or higher than 90%.

In the present embodiment, the counter electrode 120 has a trilaminar structure composed of two conducting layers and an intermediate layer located between the two conducting layers. Specifically, as shown in FIG. 1, the counter electrode 120 includes a first transparent electrode 121, a second transparent electrode 122, and an intermediate layer 123. A specific configuration of each layer will be described later.

The photelectric conversion layer 130 is located between the pixel electrode 110 and the counter electrode 120. The photoelectric conversion layer 130 internally generates an electron-hole pair upon irradiation with light. The electron-hole pair is separated into an electron and a hole by an electric field applied to the photoelectric conversion layer 130, and the electron and the hole each migrate toward the pixel electrode 110 or toward the counter electrode 120.

The photoelectric conversion layer 130 is formed of a publicly-known photoelectric conversion material. The photoelectric conversion material is for example an organic material, but may be an inorganic material. As the inorganic photoelectric conversion material, hydrogenated amorphous silicon, a compound semiconductor material, a metal-oxide semiconductor material, or other materials can be used. The compound semiconductor material is for example CdSe. The metal-oxide semiconductor material is for example ZnO.

In a case where the photoelectric conversion material is an organic material, a molecular design of the photoelectric conversion material can be comparatively freely made so that a desired photoelectric conversion characteristic is obtained. In a case where the photoelectric conversion material is an organic material, a photoelectric conversion layer 130 having a superior planarization property can be easily formed by a process of application involving the use of a solution containing the photoelectric conversion material. An organic semiconductor material can be formed, for example, by a vacuum evaporation method or a method of application.

In a case where the organic semiconductor material is used as the photoelectric conversion material, the photoelectric conversion layer 130 may be constituted by a laminated film composed of a donor material and an acceptor material, or may be constituted by a mixed film of these materials. A structure of the laminated film composed of a donor material and an acceptor material is called “heterojunction type”. A structure of the mixed film of a donor material and an acceptor material is called “bulk heterojunction type”.

A p-type semiconductor of an organic compound is a donating organic semiconductor, is typified mainly by a hole-transport organic compound, and refers to an organic compound having the property of easily donating electrons. Specifically, a p-type semiconductor of an organic compound refers to an organic compound that has a lower ionization potential when two organic compounds are used in contact with each other. Accordingly, any organic compound that has an electron-donating ability may be used as the donating organic semiconductor. Usable examples of the donating organic semiconductor include a triarylamine compound, a benzidine compound, a pyrazoline compound, a styrylamine compound, a hydrazone compound, a triphenylmethane compound, a carbazole compound, a polysilane compound, a thiophene compound, a phthalocyanine compound, a cyanine compound, a merocyanine compound, an oxonol compound, a polyamine compound, an indole compound, a pyrrole compound, a pyrazole compound, a polyallylene compound, and a metal complex having a condensed aromatic carbon ring compound or a nitrogen-containing hetero ring compound as a ligand. It should be noted that examples of the condensed aromatic carbon ring compound include a naphthalene derivative, an anthracene derivative, a phenanthrene derivative, a tetracene derivative, a pyrene derivative, a perylene derivative, and a fluoranthene derivative. Without being limited to these, any organic compound that has a lower ionization potential than an organic compound used as an accepting organic compound can be used as the donating organic semiconductor.

An n-type organic semiconductor of an organic compound is an accepting organic semiconductor, is typified mainly by an electron-transport organic compound, and refers to an organic compound having the property of easily accepting electrons. Specifically, an n-type organic semiconductor of an organic compound refers to an organic compound that has a higher electron affinity when two organic compounds are used in contact with each other. Accordingly, any organic compound that has an electron-accepting ability may be used as the accepting organic semiconductor. Usable examples of the accepting organic semiconductor include a fullerene, a fullerene derivative, a condensed aromatic carbon ring compound, a polyallylene compound, a fluorene compound, a cyclopentadiene compound, a silyl compound, and a metal complex having a nitrogen-containing hetero ring compound as a ligand. Alternatively, a metal complex having as a ligand a 5- or 7-membered hetero ring compound containing a nitrogen atom, an oxygen atom, or a sulfur atom can be used as the accepting organic compound. It should be noted that examples of the 5- or 7-membered hetero ring compound containing a nitrogen atom, an oxygen atom, or a sulfur atom include pyridine, pyrazine, pyrimidine, pyridazine, triazine, quinoline, quinoxaline, quinazoline, phthalazine, cinnoline, isoquinoline, pteridine, acridine, phenazine, phenanthroline, tetrazole, pyrazole, imidazole, thiazole, oxazole, indazole, benzimidazole, benzotriazole, benzoxazole, benzothiazole, carbazole, purine, triazolopyridazine, triazolopyrimidine, tetrazaindene, oxadiazole, imidazopyridine, pyrrolidine, pyrrolopyridine, thiadiazopyridine, dibenzazepine, and tribenzazepine. Without being limited to these, as noted above, any organic compound that has a higher electron affinity than an organic compound used as the donating organic compound can be used as the accepting organic semiconductor.

### 2. Configuration of Counter Electrode

The following describes a specific configuration of each layer of the counter electrode 120.

The first transparent electrode 121 is provided closer to the photoelectric conversion layer 130 than the second transparent electrode 122. Specifically, the first transparent electrode 121 is laminated in direct contact with an upper surface of the photoelectric conversion layer 130. The first transparent electrode 121 is transparent to visible light.

The second transparent electrode 122 is located at a side of the first transparent electrode 121 that faces away from the photoelectric conversion layer 130. Specifically, the second transparent electrode 122 is laminated in direct contact with an upper surface of the intermediate layer 123. The second transparent electrode 122 is transparent to visible light.

The first transparent electrode 121 and the second transparent electrode 122 each contain the same electrically-conductive material as a major ingredient as each other. Specifically, the first transparent electrode 121 and the second transparent electrode 122 each contain indium tin oxide (ITO) as a major ingredient. It should be noted that the electrically-conductive material that the transparent electrodes contain may be indium zinc oxide (IZO) or aluminum-doped zinc oxide (AZO).

In the present embodiment, the film thickness of the second transparent electrode 122 is greater than or equal to the film thickness of the first transparent electrode 121. For example, the film thickness of the second transparent electrode 122 is 1.5 times or more as great as, but may be twice or more as great as or four times or more as great as, the film thickness of the first transparent electrode 121. A total of the film thickness of the first transparent electrode 121 and the film thickness of the second transparent electrode 122 is approximately 50 nm. In one example, the film thickness of the first transparent electrode 121 is 10 nm, and the film thickness of the second transparent electrode 122 is 40 nm.

Further, the first transparent electrode 121 is larger in crystallite size than the second transparent electrode 122. In the present embodiment, the provision of the intermediate layer 123 inhibits crystallization of the first transparent electrode 121. Inhibition of local crystallization or other processes reduces in-plane variations in crystallite size.

Further, the second transparent electrode 122 is lower in sheet resistance than the first transparent electrode 121. For example, the sheet resistance of the second transparent electrode 122 can be decreased by decreasing the concentration of oxygen contained in a film-forming gas that is used for the film formation of the second transparent electrode 122. This makes it easy for the second transparent electrode 122 to pass an electric current in an in-plane direction orthogonal to a direction parallel with the thickness of the second transparent electrode 122, thus making it possible to enhance in-plane uniformity.

Further, the first transparent electrode 121 is greater in work function than the second transparent electrode 122. This makes the first transparent electrode 121 highly capable of injecting electrons into the photoelectric conversion layer 130.

Thus, by including a laminated structure composed of two transparent electrodes of different properties, the counter electrode 120 is highly capable of injecting electrons into the photoelectric conversion layer 130 and low in resistance.

The intermediate layer 123 is located between the first transparent electrode 121 and the second transparent electrode 122. Specifically, the intermediate layer 123 is in contact with an upper surface of the first transparent electrode 121 and a lower surface of the second transparent electrode 122. The intermediate layer 123 is transparent to visible light.

The intermediate layer 123 is formed of a material that is different from that of which both the first transparent electrode 121 and the second transparent electrode 122 are made. Specifically, the intermediate layer 123 contains an insulating material as a major ingredient. The insulating material is aluminum oxide. Alternatively, the insulating material may be silicon oxide, silicon nitride, or TEOS.

The intermediate layer 123 is provided to inhibit a change in film quality of the first transparent electrode 121. Specifically, crystallization of the first transparent electrode 121 is inhibited by the pinning effect of aluminum oxide contained in the intermediate layer 123 (see, for example, S. J. Ding et. al., “Evidence and Understanding of ALD HfO₂—Al₂O₃ Laminate MIM Capacitors Outperforming Sandwich Counterparts”, IEEE ELECTRON DEVICE LETTERS, October 2004, Vol. 25, No. 10, pp. 681-683).

The film thickness of the intermediate layer 123 needs only for example be as great as that of a layer of atoms of aluminum oxide. With variations in film thickness in the formation of the intermediate layer 123 taken into consideration, the film thickness of the intermediate layer 123 may for example be greater than or equal to 1 nm. This makes it possible to bring about a sufficient in-plane pinning effect, making it possible to inhibit in-plane crystallization of the first transparent electrode 121. The film thickness of the intermediate layer 123 may be greater than or equal to 3 nm.

Further, the intermediate layer 123 produces the tunnel effect of allowing passage of electrons. The film thickness of the intermediate layer 123 is so small as to cause the tunnel effect. J. Robertson, “High Dielectric Constant Gate Oxides for Metal Oxide Si Transistors”, Reports on Progress in Physics, December 2005, Vol. 69, No. 2, p. 327 discloses that an aluminum oxide film allows passage of electrons in a case where it has a small film thickness. Specifically, the film thickness of the intermediate layer 123 is less than or equal to 5 nm. The film thickness of the intermediate layer 123 may be less than or equal to 4 nm, less than or equal to 3 nm, or less than or equal to 2 nm. The intermediate layer 123, which allows passage of electrons, can be configured not to interfere with electrical continuity between the first transparent electrode 121 and the second transparent electrode 122.

In the present embodiment, the first transparent electrode 121, the second transparent electrode 122, and the intermediate layer 123 cover a side surface 131 of the photoelectric conversion layer 130 and a portion of the upper surface 141 of the insulating layer 140 not covered with the photoelectric conversion layer 130. Specifically, the first transparent electrode 121 is in contact with the side surface 131 of the photoelectric conversion layer 130 and the portion of the upper surface 141 of the insulating layer 140 not covered with the photoelectric conversion layer 130. The first transparent electrode 121 is in contact with the upper surface 151 of the extraction electrode 150, and is electrically connected to the extraction electrode 150.

In the present embodiment, as shown in FIG. 2, the first transparent electrode 121, the second transparent electrode 122, and the intermediate layer 123 are identical in planimetric shape to one another. For example, the first transparent electrode 121, the second transparent electrode 122, and the intermediate layer 123 each cover substantially the whole surface of the insulating layer 140.

This allows the first transparent electrode 121, the second transparent electrode 122, and the intermediate layer 123 to be patterned collectively. This makes it possible to reduce the number of patterning mask alignment steps, thus making it possible to enhance producibility of photoelectric conversion elements 100.

### 3. Manufacturing Method

An example of a method for manufacturing a photoelectric conversion element 100 having such a configuration is described.

For example, as the pixel electrode 110 and the extraction electrode 150, a titanium nitride (TiN) film with a film thickness of 50 nm is formed on top of the insulating layer 140 by sputtering and patterned into a predetermined shape. The patterning is performed, for example, by photolithography or etching. The etching is dry etching or wet etching. After the pixel electrode 110 and the extraction electrode 150 have been formed, the respective upper surfaces of the pixel electrode 110, the extraction electrode 150, and the insulating layer 140 are made flush with one another by forming an insulator film around the pixel electrode 110 and the extraction electrode 150 and patterning the insulator film. It should be noted that the step of making the upper surfaces flush with one another may be omitted.

Next, as the photoelectric conversion layer 130, an organic photoelectric conversion film that is a mixed film containing Sn(OSiHex₃)₂Nc and a fullerene (C₆₀) at a ratio of 1:9 is formed by vacuum evaporation and patterned into a predetermined shape.

Next, an ITO film with a film thickness of 10 nm is formed by sputtering. The ITO film is formed to cover the extraction electrode 150 as well as the pixel electrode 110. The composition of a target that is used in sputtering is for example InO:SnO = 9:1. Further, a mixed gas in which argon and oxygen are mixed together is introduced as the film-forming gas into a chamber in which the film is formed. It should be noted that the crystallite size of the ITO film can be adjusted by adjusting the concentration of oxygen contained in the mixed gas. Specifically, the lower the concentration of oxygen is, the smaller the crystallite size becomes, and the higher the concentration of oxygen is, the larger the crystallite size becomes.

Next, an aluminum oxide film with a film thickness of 5 nm or less is formed by atomic layer deposition (ALD).

Next, an ITO film with a film thickness of 40 nm is formed by sputtering. The formation of the second ITO film may be under the same conditions as or different conditions from the formation of the first ITO film.

Next, a trilaminar structure composed of the ITO films and the aluminum oxide film is patterned collectively, whereby the first transparent electrode 121, the intermediate layer 123, and the second transparent electrode 122, which are substantially identical in planimetric shape to one another, can be formed.

### 4. Modifications

The following describes modifications of the aforementioned photoelectric conversion element 100. The following gives a description with a focus on differences from the embodiment, and omits or simplifies a description of common features.

### 4-1. Modification 1

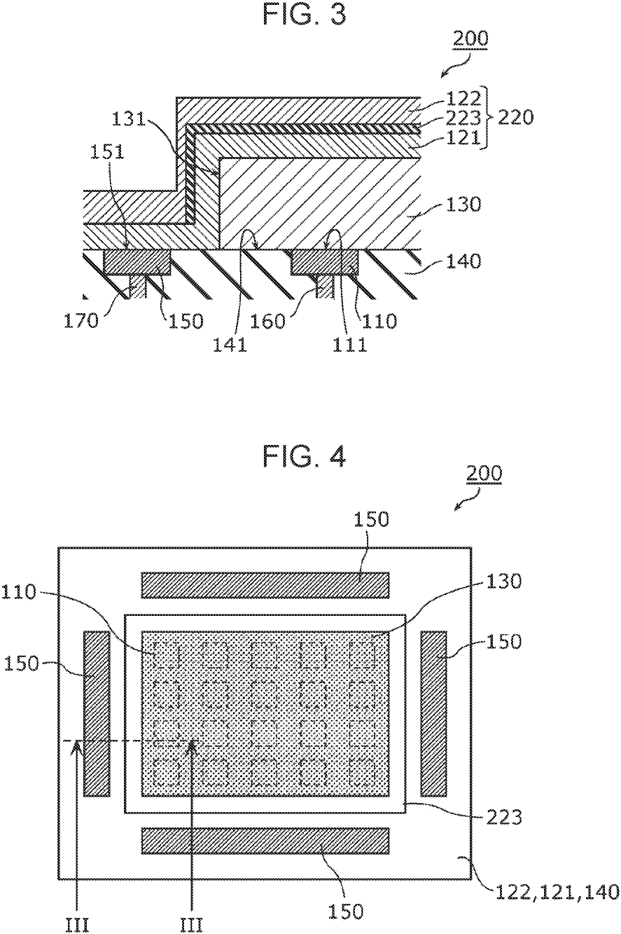

FIG. 3 is a cross-sectional view of a photoelectric conversion element 200 according to Modification 1. FIG. 4 is a plan view of the photoelectric conversion element 200 according to Modification 1. Specifically, FIG. 3 represents a cross-section taken along line III-III of FIG. 4.

The photoelectric conversion element 200 shown in FIG. 3 differs from the photoelectric conversion element 100 shown in FIG. 1 in that the photoelectric conversion element 200 includes a counter electrode 220 instead of including the counter electrode 120. The counter electrode 220 includes an intermediate layer 223 instead of including the intermediate layer 123.

The intermediate layer 223 does not overlap the extraction electrode 150 in planar view. That is, in a region overlapping the extraction electrode 150 in planar view, the second transparent electrode 122 is laminated directly on the upper surface of the first transparent electrode 121.

As shown in FIG. 4, the planimetric shape of the intermediate layer 223 is a size larger than the shape of the photoelectric conversion layer 130. In the present modification, the intermediate layer 223 covers a side surface 131 of the photoelectric conversion layer 130. Four side surfaces equivalent separately to each of the sides of the photoelectric conversion layer 130, which is rectangular in planar view, are covered. This makes it possible to inhibit characteristic degradation near the side surface of the photoelectric conversion layer 130.

In the present modification, after an aluminum oxide film on which the intermediate layer 223 is based has been formed, a portion of the aluminum oxide film overlapping the extraction electrode 150 is removed by patterning the oxide aluminum film. This makes it possible to form the intermediate layer 223 in a shape that does not cover the extraction electrode 150.

Instead of being perpendicular to the upper surface 141 of the insulating layer 140, the side surface 131 may be inclined at a slant. In this case, the intermediate layer 223 covers the side surface 131, which is an inclined surface. Further, the intermediate layer 223 may cover only one or two of the four side surfaces of the photoelectric conversion layer 130.

### 4-2. Modification 2

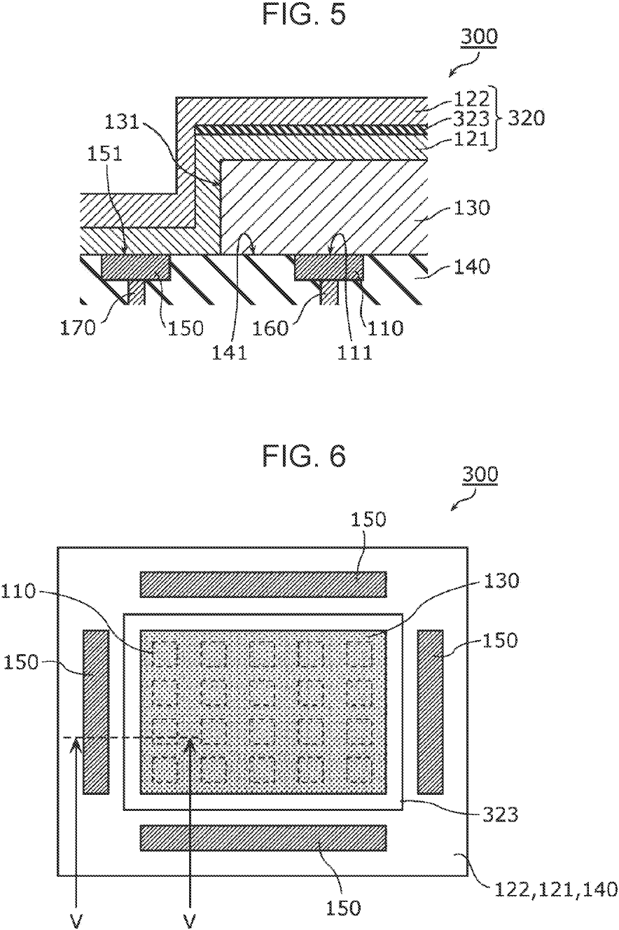

FIG. 5 is a cross-sectional view of a photoelectric conversion element 300 according to Modification 2. FIG. 6 is a plan view of the photoelectric conversion element 300 according to Modification 2. Specifically, FIG. 5 represents a cross-section taken along line V-V of FIG. 6.

The photoelectric conversion element 300 shown in FIG. 5 differs from the photoelectric conversion element 100 shown in FIG. 1 in that the photoelectric conversion element 300 includes a counter electrode 320 instead of including the counter electrode 120. The counter electrode 320 includes an intermediate layer 323 instead of including the intermediate layer 123.

The intermediate layer 323 does not overlap the extraction electrode 150 in planar view. Further, the intermediate layer 323 does not cover a side surface 131 of the photoelectric conversion layer 130. As shown in FIG. 6, the planimetric shape of the intermediate layer 323 is a size larger than the shape of the photoelectric conversion layer 130. Specifically, the intermediate layer 323 is a size smaller in shape than the intermediate layer 223 according to Modification 1. The intermediate layer 323 covers a portion of the upper surface of the first transparent electrode 121 located at the same level as a portion overlapping the photoelectric conversion layer 130 in planar view. The intermediate layer 323 may cover only part of the side surface 131.

Even in this case, variations in the optical and electrical characteristics of the first transparent electrode 121 can be reduced, as a change in film quality of the first transparent electrode 121 can be inhibited in a so-called pixel region. This makes it possible to provide an imaging device with reduced performance variations. It should be noted that the intermediate layer 323 is formed by the same method as the intermediate layer 223 according to Modification 1 except that a different mask is used for patterning.

### 4-3. Modification 3

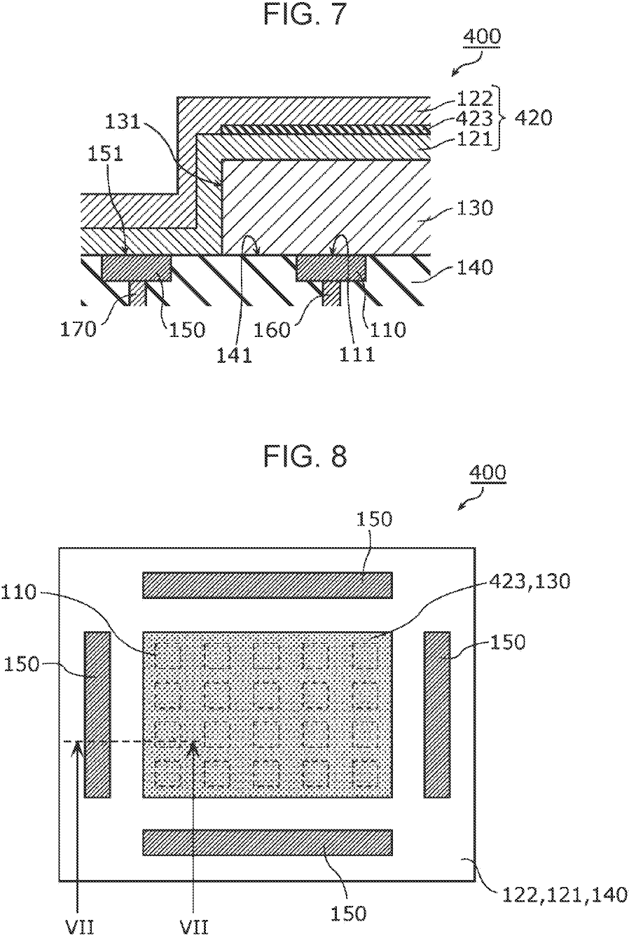

FIG. 7 is a cross-sectional view of a photoelectric conversion element 400 according to Modification 3. FIG. 8 is a plan view of the photoelectric conversion element 400 according to Modification 3. Specifically, FIG. 7 represents a cross-section taken along line VII-VII of FIG. 8.

The photoelectric conversion element 400 shown in FIG. 7 differs from the photoelectric conversion element 100 shown in FIG. 1 in that the photoelectric conversion element 400 includes a counter electrode 420 instead of including the counter electrode 120. The counter electrode 420 includes an intermediate layer 423 instead of including the intermediate layer 123.

The intermediate layer 423 does not overlap the extraction electrode 150 in planar view. Further, the intermediate layer 423 does not cover a side surface 131 of the photoelectric conversion layer 130. As shown in FIG. 8, the intermediate layer 423 is the same in shape and size as the photoelectric conversion layer 130 in planar view. The intermediate layer 423 coincide completely with the photoelectric conversion layer 130 in planar view.

Even in this case, variations in the optical and electrical characteristics of the first transparent electrode 121 can be reduced, as a change in film quality of the first transparent electrode 121 can be inhibited in a so-called pixel region. This makes it possible to provide an imaging device with reduced performance variations. It should be noted that the intermediate layer 423 is formed by the same method as the intermediate layer 223 according to Modification 1 except that a different mask is used for patterning.

### 5. Imaging Device

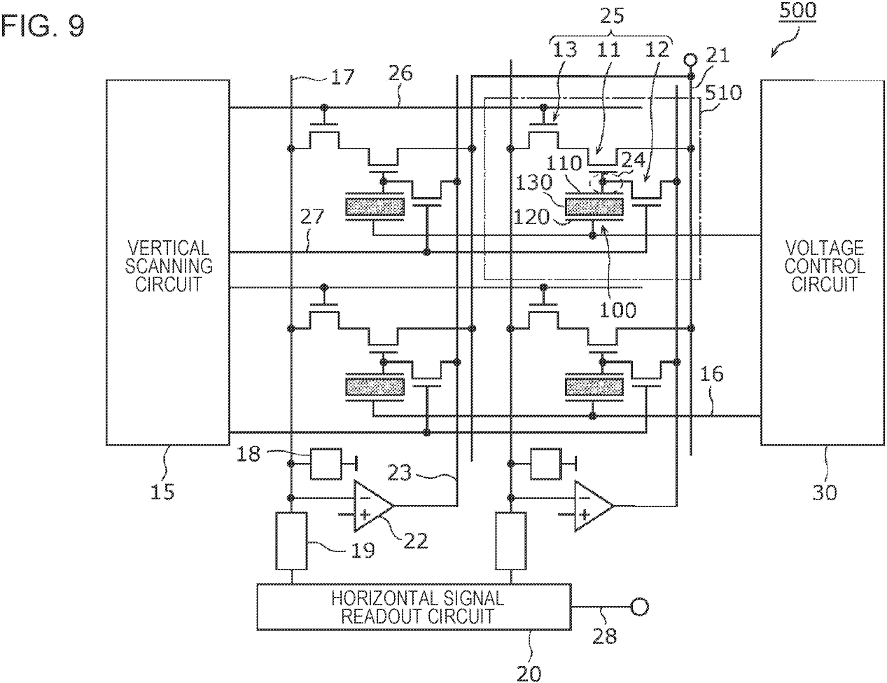

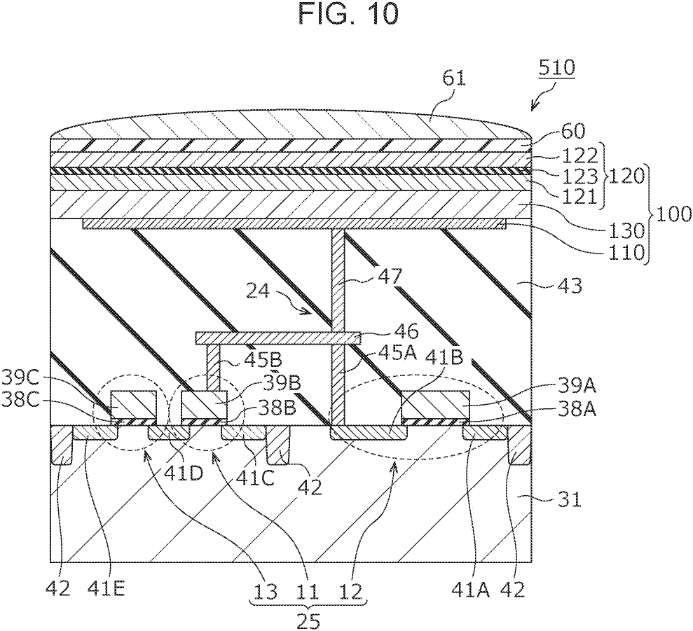

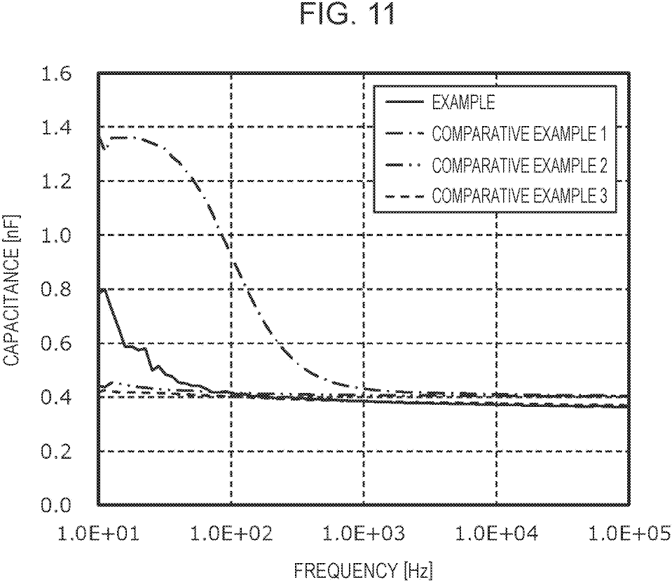

Next, an imaging device according to the present embodiment is described with reference to FIGS. 9 and 10.

FIG. 9 is a circuit diagram showing a circuit configuration of an imaging device 500 according to the present embodiment. FIG. 10 is a cross-sectional view of a unit pixel 510 of the imaging device 500 according to the present embodiment.

### 5-1. Circuit Configuration

In the following, first, the circuit configuration of the imaging device 500 according to the present embodiment is described. As shown in FIG. 9, the imaging device 500 includes a plurality of the unit pixels 510 and peripheral circuitry. Each of the plurality of unit pixels 510 includes a charge detection circuit 25, a photoelectric conversion element 100, and a charge accumulation node 24 electrically connected to the charge detection circuit 25 and the photoelectric conversion element 100.

The imaging device 500 is for example an organic image sensor that is implemented by a one-chip integrated circuit, and has a pixel array including a plurality of unit pixels 510 arrayed two-dimensionally. The plurality of unit pixels 510 are arrayed two-dimensionally, i.e. in a row-wise direction and a column-wise direction, and form a photosensitive region serving as a pixel region. FIG. 9 shows an example in which unit pixels 510 are arrayed in two rows and two columns in a matrix. The imaging device 500 may be a line sensor. In that case, the plurality of unit pixels 510 may be arrayed one-dimensionally. The terms “row-wise direction” and “column-wise direction” refer to directions in which a row and a column extend, respectively. That is, the column-wise direction is a vertical direction, and the row-wise direction is a horizontal direction.

Each of the unit pixels 510 includes a charge accumulation node 24 electrically connected to a photoelectric conversion element 100 and a charge detection circuit 25. The charge detection circuit 25 includes an amplifying transistor 11, a reset transistor 12, and an address transistor 13.

The photoelectric conversion element 100 includes a pixel electrode 110, a photoelectric conversion layer 130, and a counter electrode 120 To the counter electrode 120, a predetermined voltage is applied from a voltage control circuit 30 via a counter electrode signal line 16.

The pixel electrode 110 is connected to a gate electrode 39B (see FIG. 10) of the amplifying transistor 11. Signal charge collected by the pixel electrode 110 is accumulated in the charge accumulation node 24, which is located between the pixel electrode 110 and the gate electrode 39B of the amplifying transistor 11. In the present embodiment, the signal charge is a hole. Alternatively, the signal charge may be an electron.

The signal charge accumulated in the charge accumulation node 24 is applied to the gate electrode 39B of the amplifying transistor 11 as a voltage corresponding to the amount of signal charge. The amplifying transistor 11 amplifies this voltage. The voltage thus amplified is selectively read out as a signal voltage by the address transistor 13. The reset transistor 12 has either its source or drain electrode connected to the pixel electrode 110 and resets the signal charge accumulated in the charge accumulation node 24. In other words, the reset transistor 12 resets the potentials of the gate electrode 39B of the amplifying transistor 11 and the pixel electrode 110.

As shown in FIG. 9, the imaging device 500 has power-supply wires 21, vertical signal lines 17, address signal lines 26, and reset signal lines 27 in order to selectively perform the aforementioned operation in the plurality of unit pixels 510. These lines are connected to each of the unit pixels 510. Specifically, each of the power-supply wires 21 is connected to either source or drain electrodes of amplifying transistors 11. Each of the vertical signal lines 17 is connected to either source or drain electrodes of address transistors 13. Each of the address signal lines 26 is connected to gate electrodes 39C (see FIG. 10) of address transistors 13. Each of the reset signal lines 27 is connected to gate electrodes 39A (see FIG. 10) of reset transistors 12.

The peripheral circuitry includes a vertical scanning circuit 15, a horizontal signal readout circuit 20, a plurality of column signal processing circuits 19, a plurality of load circuits 18, a plurality of differential amplifiers 22, and a voltage control circuit 30. The vertical scanning circuit 15 is also referred to as “row scanning circuit”. The horizontal signal readout circuit 20 is also referred to as “column scanning circuit”. The column signal processing circuits 19 are also referred to as “row signal accumulation circuits”. The differential amplifiers 22 are also referred to as “feedback amplifiers”.

The vertical scanning circuit 15 is connected to the address signal lines 26 and the reset signal lines 27. The vertical scanning circuit 15 selects, on a row-by-row basis, a plurality of unit pixels 510 arranged in each row and performs a readout of signal voltages and a reset of the potentials of the pixel electrodes 110. The power-supply wires 21, which are source follower power sources, supply predetermined power supply voltages separately to each of the unit pixels 510. The horizontal signal readout circuit 20 is electrically connected to the plurality of column signal processing circuits 19. Each of the column signal processing circuits 19 is electrically connected to unit pixels 510 arranged in the corresponding column via a vertical signal line 17 belonging to the corresponding column. The load circuits 18 are electrically connected separately to each of the vertical signal lines 17. The load circuits 18 and the amplifying transistors 11 form source follower circuits.

The plurality of differential amplifiers 22 are provided separately in correspondence with each of the columns. Each of the differential amplifiers 22 has its negative input terminal connected to a corresponding one of the vertical signal lines 17. Each of the differential amplifiers 22 has its output terminal connected to unit pixels 510 via a feedback line 23 belonging to the corresponding column.

The vertical scanning circuit 15 applies, to the gate electrodes 39C of address transistors 13 through an address signal line 26, a row selection signal that controls the turning on and turning off of the address transistors 13. In this way, a row to be read out is scanned and selected. Signal voltages are read out from the selected row of unit pixels 510 to the vertical signal line 17. The vertical scanning circuit 15 applies, to the gate electrodes 39A of reset transistors 12 via a reset signal line 27, a reset signal that controls the turning on and turning off of the reset transistors 12. In this way, a row of unit pixels 510 to be subjected to a reset operation is selected. Each of the vertical signal lines 17 transmits, to a corresponding one of the column signal processing circuits 19, signal voltages read out from unit pixels 510 selected by the vertical scanning circuit 15.

The column signal processing circuits 19 perform noise suppression signal processing, which is typified by correlated double sampling, analog-to-digital conversion (AD conversion), or other processing.

The horizontal signal readout circuit 20 reads out signals in sequence from the plurality of column signal processing circuits 19 to a horizontal common signal line 28.

Each of the differential amplifiers 22 is electrically connected via a feedback line 23 to the others of the source and drain electrodes of reset transistors 12 that are not connected to the pixel electrodes 110. Accordingly, each of the differential amplifiers 22 receives output values from address transistors 13 through its negative input terminal when the address transistors 13 and the reset transistor 12 are electrically continuous. Each of the differential amplifiers 22 performs a feedback operation so that the gate potentials of amplifying transistors 11 become predetermined feedback voltages. At this point in time, the output voltage value of the differential amplifier 22 is 0 V or a positive voltage of nearly 0 V. The term “feedback voltage” means an output voltage of a differential amplifier 22.

The voltage control circuit 30 may generate a constant control voltage or may generate a plurality of control voltages of different values. For example, the voltage control circuit 30 may generate two or more control voltages of different values or may generate a control voltage that continuously varies within a predetermined range. The voltage control circuit 30 determines, in accordance with an instruction from an operator who operates the imaging device 500 or an instruction from another controller of the imaging device 500, the value of a control voltage to be generated and generates a control voltage value of the value thus determined. The voltage control circuit 30 is provided outside the photosensitive region as part of the peripheral circuitry. It should be noted that the photosensitive region is substantially identical to the pixel region.

For example, when the voltage control circuit 30 generates two or more control voltages of different values and applies the control voltages to counter electrodes 120, variations are caused in spectral-response characteristic of the photoelectric conversion layer 130. Further, this spectral-response characteristic varies within a range including such a spectral-response characteristic that the sensitivity of the photoelectric conversion layer 130 to light to be detected becomes zero. In this way, for example, during a readout of detection signals by unit pixels 510 for each row in the imaging device 500, the effect of light that is incident during the readout of the detection signals can be substantially eliminated by applying such control voltages to the counter electrodes 120 from the voltage control circuit 30 that the sensitivity of the photoelectric conversion layer 130 becomes zero. Therefore, even when detection signals are read out substantially for each row, a global shutter operation can be achieved.

In the present embodiment, as shown in FIG. 9, the voltage control circuit 30 applies control voltages via a counter electrode signal line 16 to the counter electrode 120 of unit pixels 510 arrayed in a row-wise direction. By so doing, the voltage control circuit 30 effects changes in voltage between the pixel electrodes 110 and the counter electrode 120 and switches spectral-response characteristics in the photoelectric conversion element 100. Alternatively, the voltage control circuit 30 achieves an electronic shutter operation by applying a control voltage so that such a spectral-response characteristic is obtained that the sensitivity to light becomes zero at a predetermined timing during imaging. It should be noted that the voltage control circuit 30 may apply control voltages to the pixel electrodes 110.

In order for the photoelectric conversion element 100 to be irradiated with light and for the pixel electrodes 110 to trap electrons as signal charge, the pixel electrodes 110 are set at a higher potential than the counter electrode 120. This causes the electrons to migrate toward the pixel electrodes 110. At this point in time, electric currents flow from the pixel electrodes 110 toward the counter electrode 120, as the direction of migration of electrons is opposite to the direction of flow of an electric current. Further, in order for the photoelectric conversion element 100 to be irradiated with light and for the pixel electrodes 110 to trap holes as signal charge, the pixel electrodes 110 are set at a lower potential than the counter electrode 120. At this point in time, electric currents flow from the counter electrode 120 toward the pixel electrodes 110.

### 5-2. Cross-Section Configuration

Next, an example of a specific cross-section configuration of a unit pixel 510 of the imaging device 500 is described with reference to FIG. 10. As shown in FIG. 10, the unit pixel 510 includes a semiconductor substrate 31, a charge detection circuit 25, a photoelectric conversion element 100, and a charge accumulation node 24. A plurality of the unit pixels 510 are formed on the semiconductor substrate 31. For example, the photoelectric conversion element 100 is provided above the semiconductor substrate 31. The charge detection circuit 25 is provided inside and above the semiconductor substrate 31.

The semiconductor substrate 31 is an insulating substrate or other substrates having a semiconductor layer provided on a surface thereof on which the photosensitive region is formed and, for example, is a p-type silicon substrate. The semiconductor substrate 31 has impurity regions 41A. 41B, 41C, 41D, and 41E and an element separation region 42 for electrical separation between unit pixels 510. In this example, the element separation region 42 is also provided between the impurity region 41B and the impurity region 41C. This reduces leakage of signal charge accumulated in the charge accumulation node 24. It should be noted that the element separation region 42 is formed, for example, by performing ion implantation of acceptors under predetermined implantation conditions.

The impurity regions 41A. 41B, 41C, 41D, and 41E are for example diffusion layers formed in the semiconductor substrate 31. In this example, the impurity regions 41A. 41B, 41C, 41D, and 41E are n-type impurity regions. As shown in FIG. 10, the amplifying transistor 11 includes the impurity region 41C, the impurity region 41D, a gate insulator film 38B, and the gate electrode 39B. The impurity region 41C and the impurity region 41D function as source and drain regions, respectively, of the amplifying transistor 11. The amplifying transistor 11 has its channel region formed between the impurity region 41C and the impurity region 41D.

Similarly, the address transistor 13 includes the impurity region 41D, the impurity region 41E, a gate insulator film 38C, and the gate electrode 39C. In the example shown in FIG. 10, the amplifying transistor 11 and the address transistor 13 are electrically connected to each other by sharing the impurity region 41D with each other. The impurity region 41D and the impurity region 41E function as source and drain regions, respectively, of the address transistor 13. The impurity region 41E is connected to a vertical signal line 17 shown in FIG. 9.

The reset transistor 12 includes the impurity region 41A, the impurity region 41B, a gate insulator film 38A, and the gate electrode 39A. The impurity region 41A and the impurity region 41B function as source and drain regions, respectively, of the reset transistor 12. The impurity region 41A is connected to a reset signal line 27 shown in FIG. 9.

The gate insulator film 38A, the gate insulator film 38B, and the gate insulator film 38C are each an insulator film formed of an insulating material. The insulator film has, for example, a single-layer structure or laminated structure of a silicon oxide film or a silicon nitride film.

The gate electrode 39A, the gate electrode 39B, and the gate electrode 39C are each formed of an electrically-conductive material. The electrically-conductive material is for example electrically-conductive polysilicon.

On top of the semiconductor substrate 31, an interlayer insulating layer 43 is laminated in such a way as to cover the amplifying transistor 11, the address transistor 13, and the reset transistor 12. In the interlayer insulating layer 43, a wiring layer (not illustrated) may be placed. The wiring layer is formed from metal such as copper and, for example, may include wires such as the aforementioned vertical signal lines 17 as parts thereof. The number of insulating layers in the interlayer insulating layer 43 and the number of layers that are included in the wiring layer placed in the interlayer insulating layer 43 may be set to arbitrary values.

The interlayer insulating layer 43 has placed therein a contact plug 45A connected to the impurity region 41B of the reset transistor 12, a contact plug 45B connected to the gate electrode 39B of the amplifying transistor 11, a contact plug 47 connected to the pixel electrode 110, and a wire 46 connecting the contact plug 47, the contact plug 45A, and the contact plug 45B with one another. This causes the impurity region 41B of the reset transistor 12 to be electrically connected to the gate electrode 39B of the amplifying transistor 11.

On top of the interlayer insulating layer 43, the photoelectric conversion element 100 is placed. A specific configuration of the photoelectric conversion element 100 is the same as that shown in FIG. 1. It should be noted that the interlayer insulating layer 43 and the contact plug 47 are equivalent to the insulating layer 140 and the connecting wire 160, which are shown in FIG. 1, respectively. The extraction electrode 150 and the connecting wire 170, which are shown in FIG. 1, are not provided, for example, in a unit pixel 510 but provided in a peripheral edge portion of the photosensitive region.

It should be noted that the imaging device 500 may include a photoelectric conversion element 200, 300, or 400 instead of including the photoelectric conversion element 100.

A color filter 60 is provided above the photoelectric conversion element 100. A microlens 61 is provided above the color filter 60. The color filter 60 is for example formed as an on-chip color filter by patterning. As a material of which the color filter 60 is made of, photosensitive resin or other substances having a dye or a pigment is dispersed therein are used. The microlens 61 is provided, for example, as an on-chip microlens. As a material of which the microlens 61 is made of, an ultraviolet-sensitive material or other materials are used.

The imaging device 500 can be manufactured using a common semiconductor manufacturing process. In particular, in a case where a silicon substrate is used as the semiconductor substrate 31, the imaging device 500 can be manufactured using various silicon semiconductor processes.

As noted above, the counter electrode 120 of the photoelectric conversion element 100 of the imaging device 500 has a laminated structure composed of the first transparent electrode 121, the intermediate layer 123, and the second transparent electrode 122. For this reason, as mentioned above, the imaging device 500 has reduced in-plane characteristic variations and, with the counter electrode 120, which is highly capable of injecting electrons, can achieve both reduced characteristic variations of the photoelectric conversion element 100 and improved controllability of current-voltage characteristics.

It should be noted that a translucent and insulating protective film may be provided between the photoelectric conversion element 100 and the color filter 60.

In the following, a photoelectric conversion element or other components that are used in an imaging device according to the present disclosure are described in concrete terms by way of Example. However, the present disclosure is not intended to be limited in any way to the following Example alone.

### EXAMPLE

A photoelectric conversion element of Example was fabricated according to the following procedure.

On a substrate having TiN formed as a lower electrode therein, a photoelectric conversion layer 130 with a thickness of 500 nm was formed by vapor deposition. Next, an ITO film with a thickness of 10 nm was formed as a first transparent electrode by sputtering. Next, an Al₂O₃ film with a thickness of 3 nm was formed as an insulating layer by atomic layer deposition. Next, an ITO film with a thickness of 40 nm was formed as a second transparent electrode by sputtering. Furthermore, an Al₂O₃ film with a thickness of 60 nm was formed as a sealing film on top of the second transparent electrode by atomic layer deposition. After that, the substrate thus fabricated was heated at 200° C. for 50 minutes in a nitrogen atmosphere, whereby the photoelectric conversion element of Example was obtained.

### Comparative Example 1

On a substrate having TiN formed as a lower electrode therein, a photoelectric conversion layer 130 with a thickness of 500 nm was formed by vapor deposition, and an ITO film with a thickness of 10 nm was formed as a first transparent electrode by sputtering. Next, an Al₂O₃ film with a thickness of 60 nm was formed as a sealing film on top of the first transparent electrode by atomic layer deposition. After that, the substrate thus fabricated was heated at 200° C. for 50 minutes in a nitrogen atmosphere, whereby a photoelectric conversion element of Comparative Example 1 was obtained.

### Comparative Example 2

On a substrate having TiN formed as a lower electrode therein, a photoelectric conversion layer 130 with a thickness of 500 nm was formed by vapor deposition, and an ITO film with a thickness of 10 nm was formed as a first transparent electrode by sputtering. Next, an Al₂O₃ film with a thickness of 0.4 nm was formed as an insulating layer on top of the first transparent electrode by atomic layer deposition. Next, an ITO film with a thickness of 40 nm was formed as a second transparent electrode by sputtering. Next, an Al₂O₃ film with a thickness of 60 nm was formed as a sealing film on top of the second transparent electrode by atomic layer deposition. After that, the substrate thus fabricated was heated at 200° C. for 50 minutes in a nitrogen atmosphere, whereby a photoelectric conversion element of Comparative Example 2 was obtained.

### Comparative Example 3

On a substrate having TiN formed as a lower electrode therein, a photoelectric conversion layer 130 with a thickness of 500 nm was formed by vapor deposition, and an ITO film with a thickness of 10 nm was formed as a first transparent electrode by sputtering. Next, an Al₂O₃ film with a thickness of 2.5 nm was formed as an insulating layer on top of the first transparent electrode by atomic layer deposition. Next, an ITO film with a thickness of 40 nm was formed as a second transparent electrode by sputtering. Next, an Al₂O₃ film with a thickness of 60 nm was formed as a sealing film on top of the second transparent electrode by atomic layer deposition. After that, the substrate thus fabricated was heated at 200° C. for 50 minutes in a nitrogen atmosphere, whereby a photoelectric conversion element of Comparative Example 3 was obtained. Measurements of Frequency-capacitance Characteristics under Dark Conditions

Frequency-capacitance characteristics of the photoelectric conversion elements of Example, Comparative Example 1, Comparative Example 2, and Comparative Example 3 under dark conditions were measured. Measurements of the frequency-capacitance characteristics involved the use of Keysight’s semiconductor parameter analyzer B1500A, and were performed by measuring the capacitances of the photoelectric conversion layers with frequencies swept from 10 Hz to 100000 Hz.

### Evaluation Results

FIG. 11 shows results of measurement of the frequency-capacitance characteristics of the photoelectric conversion elements under dark conditions in Example and Comparative Examples 1 to 3. In FIG. 11, the solid line indicates the result of measurement of the photoelectric conversion element of Example, the dot-and-dash line the result of measurement of the photoelectric conversion element of Comparative Example 1, the chain double-dashed line the result of measurement of the photoelectric conversion element of Comparative Example 2, and the dotted line the result of measurement of the photoelectric conversion element of Comparative Example 3. Further, Table 1 shows results of measurement of the capacitances of the photoelectric conversion elements at 10 Hz under dark conditions in Example and Comparative Examples 1 to 3.

As shown in FIG. 11 and Table 1, Example exhibited an increase in capacitance of the photoelectric conversion layer in a low-frequency region due to the effect of injection of electrons from the first transparent electrode into the photoelectric conversion layer as can be seen in Comparative Example 1. Meanwhile, neither Comparative Example 2 nor 3 exhibited any increase in capacitance of the photoelectric conversion layer in a low-frequency region, as the insulating layer between the first transparent electrode and the second transparent electrode was thin. A possible reason for this is that the separation of the first transparent electrode and the second transparent electrode was not so sufficient as to bring about the effect of inhibiting crystallization of the first transparent electrode.

TABLE 1

| | | | | | |
|---|---|---|---|---|---|
| | Photoelectric conversion layer | First transparent electrode | Insulating layer | Second transparent electrode | Capacitance |
| Example | 500 nm | 10 nm | 3 nm | 40 nm | 0.78 nF |
| Comparative Example 1 | 500 nm | 10 nm | NA | NA | 1.37 nF |
| Comparative Example 2 | 500 nm | 10 nm | 0.4 nm | 40 nm | 0.44 nF |
| Comparative Example 3 | 500 nm | 10 nm | 2.5 nm | 40 nm | 0.42 nF |

In light of the foregoing, a method of the present disclosure makes it possible to provide a photoelectric conversion element with improvement in both in-plane uniformity and property of injection of charge from the first transparent electrode and with superiority in control of frequency characteristics of capacitances.

### Other Embodiments

In the foregoing, imaging devices according to one or more aspects have been described with reference to embodiments. However, the present disclosure is not intended to be limited to these embodiments. Applications to the present embodiments of various types of modification conceived of by persons skilled in the art and embodiments constructed by combining constituent elements of different embodiments are encompassed in the scope of the present disclosure, provided such applications and embodiments do not depart from the scope of the present disclosure.

For example, in the embodiment described above, one or more functional layers having predetermined functions may be provided between the photoelectric conversion layer 130 and the pixel electrode 110 and/or between the photoelectric conversion layer 130 and the counter electrode 120. The one or more functional layers are for example electron block layers that transmit holes and block electrons, hole block layers that transmit electrons and block holes, or other layers. For example, in a case where the pixel electrode 110 traps holes as signal charge, an electron block layer may be provided between the photoelectric conversion layer 130 and the pixel electrode 110, and a hole block layer may be provided between the photoelectric conversion layer 130 and the counter electrode 120.

As a material of which the electron block layer is formed, a p-type semiconductor or a hole-transport organic compound can be used. Examples of such materials include aromatic diamine compounds such as TPD (N,N′-bis(3-methylphenyl)-(1,1′-biphenyl)-4,4′diamine) and α-NPD (4,4′-bis[N-(naphthyl)-N-phenyl-amino]biphenyl), oxazole, oxadiazole, triazole, imidazole, imidazolone, a stilbene derivative, a pyrazoline derivative, tetrahydroimidazole, polyarylalkane, butadiene, m-MTDATA (4,4′,4″-tris(N-(3-methylphenyl)N-phenylamino)triphenylamine), perylene, porphyrin compounds such as porphin, copper tetraphenylporphin, phthalocyanine, copper phthalocyanine, and titanium phthalocyanine oxide, a triazole derivative, an oxadiazole derivative, an imidazole derivative, a polyarylalkane derivative, a pyrazoline derivative, a pyrazolone derivative, a phenylenediamine derivative, an arylamine derivative, an amino-substituted chalcone derivative, an oxazole derivative, a styrylanthracene derivative, a fluorenone derivative, a hydrazone derivative, and a silazane derivative. Alternatively, as the material of which the electron block layer is formed, polymers such as phenylenevinylene, fluorene, carbazole, indole, pyrene, pyrrole, picoline, thiophene, acetylene, and diacetylene or derivatives thereof can be used. The material of which the electron block layer is formed may be selected from among the foregoing materials in consideration of the electron affinity of a material that constitutes the photoelectric conversion layer 130. The electron block layer may be formed of an inorganic material as well as an organic material.

As a material of which the hole block layer is formed, an n-type semiconductor or an electron-transport organic compound can be used. Examples of such materials include fullerenes such as C₆₀ and C₇₀, a fullerene derivative such as indene-C₆₀ bisadduct (ICBA), a carbon nanotube and a derivative thereof, an oxadiazole derivative such as OXD-7 (1,3-bis(4-tert-butylphenyl-1,3,4-oxadiazolyl)phenylene), an anthraquinodimethane derivative, a diphenylquinone derivative, bathocuproine(BCP), bathophenanthroline and a derivative thereof, a distyrylarylene derivative, a triazole compound, a silole compound, a tris(8-hydroxyquinolinate )aluminum complex, a bis(4-methyl-8-quinolinate)aluminum complex, an acetylacetonate derivative, copper phthalocyanine, 3,4,9,10-perylenetetracarboxylic dianhydride (PTCDA), an organic substance or organometal compound such as Alq, and inorganic substances such as MgAg and MgO. The material of which the hole block layer is formed may be selected from among the foregoing materials in consideration of the ionization potential of a material that constitutes the photoelectric conversion layer 130.

Further, for example, the light that the photoelectric conversion layer 130 photoelectrically converts may be infrared light or ultraviolet light. In this case, the first transparent electrode 121, second transparent electrode 122, and intermediate layer 123 of the counter electrode 120 are transparent to infrared light or ultraviolet light.

Further, each of the embodiments described above is subject, for example, to various changes, substitutions, additions, and omissions in the scope of the claims or the scope of equivalents thereof.

The present disclosure can be utilized as an imaging device with reduced performance variations and, for example, can be utilized in a camera, a ranging device, or other devices.

What is claimed is:

1. An imaging device comprising:
at least one pixel electrode;
a counter electrode facing the at least one pixel electrode; and
a photoelectric conversion layer located between the at least one pixel electrode and the counter electrode, wherein
the counter electrode includes
a first transparent electrode,
a second transparent electrode, and
an intermediate layer located between the first transparent electrode and the second transparent electrode,
a material of the intermediate layer is different from a material of the first transparent electrode,
the material of the intermediate layer is different from a material of the second transparent electrode,
the photoelectric conversion layer, the first transparent electrode, the intermediate layer, and the second transparent electrode are arranged in this order, and
the intermediate layer contains an insulating material as a major ingredient.

2. The imaging device according to claim 1, wherein the intermediate layer has a film thickness greater than or equal to 3 nm.

3. The imaging device according to claim 2, wherein the insulating material is aluminum oxide.

4. The imaging device according to claim 1, wherein the intermediate layer has a film thickness less than or equal to 5 nm.

5. The imaging device according to claim 1, wherein the first transparent electrode is larger in crystallite size than the second transparent electrode.

6. The imaging device according to claim 1, wherein the first transparent electrode and the second transparent electrode each contain indium tin oxide as a major ingredient.

7. The imaging device according to claim 1, wherein
the at least one pixel electrode includes a plurality of pixel electrodes,
the plurality of pixel electrodes are arranged in a matrix in a plan view, and
the intermediate layer is provided across the plurality of pixel electrodes in the plan view.

8. The imaging device according to claim 7, further comprising an extraction electrode placed in a position that is different from a position of each of the plurality of pixel electrodes in the plan view and that is electrically connected to the counter electrode, wherein
the first transparent electrode and the second transparent electrode overlap the extraction electrode in the plan view, and
the first transparent electrode is in contact with the extraction electrode.

9. The imaging device according to claim 8, wherein the intermediate layer overlaps the extraction electrode in the plan view.

10. The imaging device according to claim 8, wherein the intermediate layer does not overlap the extraction electrode in the plan view.

11. The imaging device according to claim 10, wherein the intermediate layer covers a side surface of the photoelectric conversion layer.
